(19) United States
(12) Patent Application Publication
(10) Pub. No.: US 2023/0313378 A1
(43) Pub. Date: Oct. 5, 2023

(54) METHODS OF PREVENTING METAL CONTAMINATION BY CERAMIC HEATER

(71) Applicant: Applied Materials, Inc., Santa Clara, CA (US)

(72) Inventors: Yongjing Lin, San Jose, CA (US); Lei Zhou, San Jose, CA (US); Muhannad Mustafa, Milpitas, CA (US); Shih Chung Chen, Cupertino, CA (US); Zhihui Liu, Sunnyvale, CA (US); Chi-Chou Lin, San Jose, CA (US); Bin Cao, Fremont, CA (US); Janardhan Devrajan, Santa Clara, CA (US); Mario D. Silvetti, Fountain Hills, AZ (US); Mandyam Sriram, San Jose, CA (US)

(73) Assignee: Applied Materials, Inc., Santa Clara, CA (US)

(21) Appl. No.: 17/709,931

(22) Filed: Mar. 31, 2022

(51) Int. Cl. C23C 16/458; C23C 16/455

(52) U.S. Cl. CPC C23C 16/4586; C23C 16/45544

(57) ABSTRACT

Substrate support, substrate support assemblies and process chambers comprising same are described. The substrate support has a thermally conductive body with a top surface, a bottom surface and an outer edge, and a plurality of long edge purge channel outlet opening at the outer edge of the thermally conductive body. The substrate support is configured to support a substrate to be processed on a top surface of the substrate support. The top surface of the thermally conductive body may have a ceramic coating. Each of the plurality of purge channel outlet is in fluid communication with a long edge purge channel. The long edge purge channel is coated with a long edge purge channel coating. A substrate support assembly includes the substrate support and the support post coupled to the substrate support. The processing chamber include a chamber body and the substrate support within the chamber body.

### TECHNICAL FIELD

Embodiments described herein are generally related to preventing metal contamination by a substrate support pedestal, and more specifically, a substrate support pedestal that allows rapid heating and cooling of a substrate disposed on the substrate support pedestal.

### BACKGROUND

Semiconductor technology has advanced at a rapid pace and device dimensions have shrunk with advancing technology to provide faster processing and storage per unit space. Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased. Therefore, as semiconductor technology advances, the market demands increasing smaller chips with increasingly more structures per unit area.

As the devices have continued to scale down, the requirement for metal contamination specification is becoming more and more important. Particularly, the metal contamination in thin film deposition process needs to be tightly controlled to avoid impacting device performance. The substrate support pedestal with a pedestal heater, where the substrate is disposed on during the process, is a key contributor of metal contamination.

Therefore, there is a need in the art for an improved the substrate support pedestal for use during the thin film deposition processes.

### SUMMARY

One or more embodiments of the disclosure are related to substrate supports. The substrate supports comprise a thermally conductive body having a top surface, a bottom surface and an outer edge. A ceramic coating is on the top surface of the thermally conductive body. The substrate supports include a plurality of long edge purge channel outlets. A long edge purge channel is coated with a long edge purge coating. The substrate supports are configured to support a substrate to be processes on the top surface of the thermally conductive body. The plurality of long edge purge channel outlets opens at the outer edge of the thermally conductive body. Each of the plurality of long edge purge channel outlets are in fluid communication with a long edge purge channel.

Additional embodiments of the disclosure are related to substrate support assemblies comprising a substrate support and a substrate support post coupled to the substrate support. The substrate supports comprise a thermally conductive body having a top surface, a bottom surface and an outer edge. The substrate supports are configured to support a substrate to be processed on the top surface of the thermally conductive body. The support post comprises a long edge purge channel coated with a long edge purge channel coating. The long edge purge channel is in fluid communication with a long edge purge outlet that opens at the outer edge of the thermally conductive body.

One or more embodiments of the disclosure are related to processing chambers comprising a chamber body and a substrate support within the chamber body. The substrate support comprises a thermally conductive body having a top surface, a bottom surface and an outer edge, a ceramic coating on the top surface of the thermally conductive body, a plurality of long edge purge channel outlet opening at the outer edge of the thermally conductive body, a first heating element disposed within an outer zone of the thermally conductive body, a second heating element disposed within an inner zone of the thermally conductive body, and a third heating element disposed within a central zone of the thermally conductive body. The thermally conductive body comprises Al, Ti, Si, oxides of Al, Ti or Si, nitrides of Al, Ti or Si, or combinations thereof. The substrate support is configured to support a substrate to be processed on the top surface of the thermally conductive body. The ceramic coating comprises AlOₓ, TiNₓ, TiOₓ, TiSiN, SiOₓ, SiN, AlN or combinations thereof. Tach of the plurality of long edge purge channel outlet is in fluid communication with a long edge purge channel. The long edge purge channels are coated with a long edge purge channel coating comprising AlOₓ, TiNₓ, TiOₓ, TiSiN, SiOₓ, SiN, AlN or combinations thereof.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 shows a cross-sectional isometric view of a processing chamber in accordance with one or more embodiment of the disclosure;

FIG. 2 shows a cross-sectional view of a processing chamber in accordance with one or more embodiment of the disclosure;

FIG. 3 is a bottom isometric view of a support assembly in accordance with one or more embodiment of the disclosure;

FIG. 4 is a top isometric view of a support assembly in accordance with one or more embodiment of the disclosure;

FIG. 5 is a partial cross-sectional schematic view of a support assembly in accordance with one or more embodiment of the disclosure;

FIG. 6 is a cross-sectional schematic view of a substrate support according to one or more embodiment of the disclosure;

FIG. 7 is an azimuthal cross-sectional schematic view of a substrate support taken along line 6-6′ in FIG. 6;

FIG. 8 is a cross-sectional schematic view of a substrate support according to one or more embodiment of the disclosure;

FIG. 9 is a cross-sectional schematic view of an electrostatic chuck taken along line 7-7′ in FIG. 6; and

FIG. 10 is a schematic representation of a processing platform in accordance with one or more embodiment of the disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

Embodiments of the disclosure relate to pedestal designs to prevent metal contamination of the substrate when processing at high temperature. Specifically, the method provides thin film coating of a support surface and a long edge purge channel of the pedestal blocking metal contamination of the substrate. In some embodiments, the support surface comprises a heater. In some embodiments, the support surface is operatively connected to the heater. The heater is configured to control temperature of the support surface during the processing. In some embodiments, the thin film coating of the support surface blocks metal diffusion from heater to the substrate during the processing.

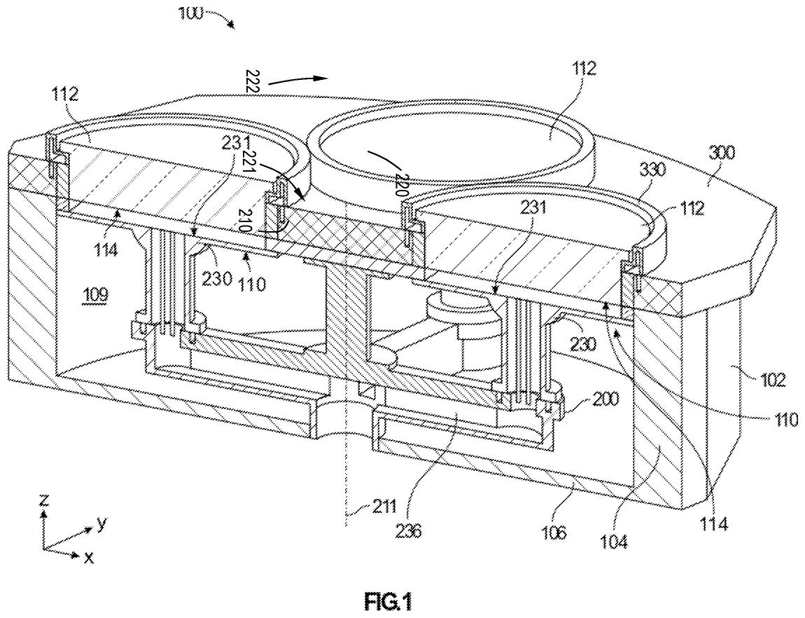

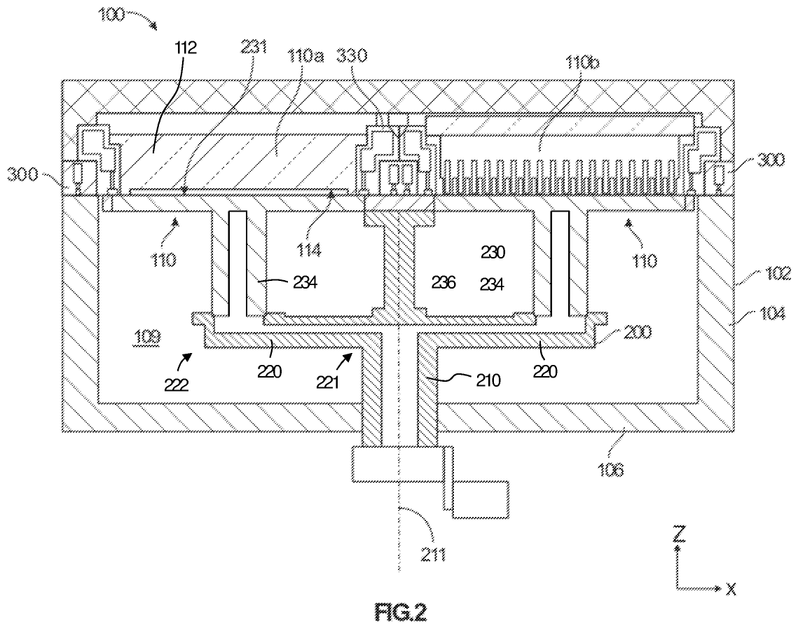

In one or more embodiments, the disclosure describes a substrate support pedestal. FIGS. 1 and 2 illustrate a batch processing chamber 100 in accordance with one or more embodiment of the disclosure. FIG. 1 shows the processing chamber 100 illustrated as a cross-sectional isometric view in accordance with one or more embodiment of the disclosure. FIG. 2 shows a processing chamber 100 in cross-section according to one or more embodiment of the disclosure.

The processing chamber 100 has a housing 102 with walls 104 and a bottom 106. The housing 102 along with the top plate 300 define a interior volume 109, also referred to as a processing volume.

The processing chamber 100 illustrated includes a plurality of processing stations 110. The processing stations 110 are located in the interior volume 109 of the housing 102 and are positioned in a circular arrangement around the rotational axis 211 of the support assembly 200. Each processing station 110 comprises a gas injector 112 (also referred to as a gas distribution plate) having a front surface 114. The processing stations 110 are defined as a region in which processing can occur. For example, in some embodiments, a processing station 110 is defined as a region bounded by the support surface 231 of the support assembly 200, as described below, and the front surface 114 of the gas injectors 112. In the illustrated embodiment, heaters 230 act as the substrate support surfaces and form part of the support assembly 200.

The processing stations 110 can be configured to perform any suitable process and provide any suitable process conditions. The type of gas injector 112 used will depend on, for example, the type of process being performed and the type of showerhead or gas injector. For example, a processing station 110 configured to operate as an atomic layer deposition apparatus may have a showerhead or vortex type gas injector. Whereas a processing station 110 configured to operate as a plasma station may have one or more electrode and/or grounded plate configuration to generate a plasma while allowing a plasma gas to flow toward the substrate. The embodiment illustrated in FIG. 2 has a different type of processing station 110 on the left side (processing station 110a) of the drawing than on the right side (processing station 110b) of the drawing. Suitable processing stations 110 include, but are not limited to, thermal processing stations, microwave plasma, three-electrode CCP, ICP, parallel plate CCP, UV exposure, laser processing, pumping chambers, annealing stations and metrology stations.

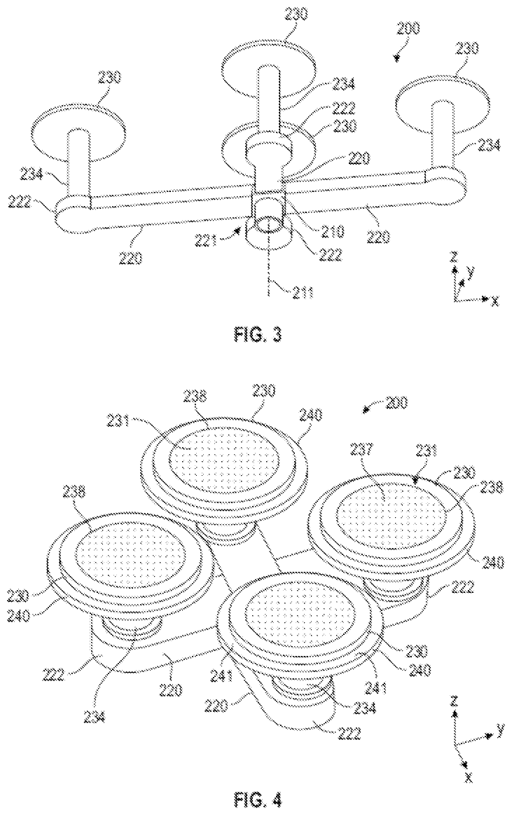

FIGS. 3 through 5 illustrate support assemblies 200 in accordance with one or more embodiments of the disclosure. The support assembly 200 includes a rotatable center base 210. The rotatable center base 210 can have a symmetrical or asymmetrical shape and defines a rotational axis 211. The rotational axis 211, as can be seen in FIGS. 1 through 3, extends in a first direction. The first direction may be referred to as the vertical direction or along the z-axis. The use of the term “vertical” is not limited to a direction parallel to the pull of gravity, and the use of the term “horizontal” is not limited to a direction normal to the pull of gravity.

The support assembly 200 includes at least two support arms 220 connected to and extending from the center base 210. The support arms 220 have an inner end 221 and an outer end 222. The inner end 221 is in contact with the center base 210 so that when the center base 210 rotates around the rotational axis 211, the support arms 220 rotate as well. In some embodiments, the support arms 220 extend orthogonal to the rotational axis 211 so that the outer ends 222 are further from the rotational axis 211 than the inner ends 221 of the same support arm 220.

The support arms 220 can be connected to the center base 210 by any suitable manner known to the skilled artisan. For example, in some embodiments, the inner end 221 is connected to the center base 210 by use of fasteners (e.g., bolts). In some embodiments, the inner end 221 is integrally formed with the center base 210.

The number of support arms 220 in the support assembly 200 can vary. In some embodiments, there are at least two support arms 220, at least three support arms 220, at least four support arms 220, or at least five support arms 220. In some embodiments, there are three support arms 220. In some embodiments, there are four support arms 220. In some embodiments, there are five support arms 220. In some embodiments, there are six support arms 220.

The support arms 220 of some embodiments are arranged symmetrically around the center base 210. For example, in a support assembly 200 with four support arms 220, each of the support arms 220 are positioned at 90° intervals around the center base 210 so that an axis formed by the support arms 220 are perpendicular to an axis formed by an adjacent (not across the rotation axis 211) support arm 220. Stated differently, in embodiments with four support arms 220, the support arms are arranged to provide four-fold symmetry around the rotation axis 211. In a support assembly 200 with three support arms 220, the support arms 220 are positioned at 120° intervals around the center base 210 so that an axis formed by the support arms 220 are at a 120° angle to the other support arms 220. In some embodiments, the support assembly 200 has n-number of support arms 220 and the n-number of support arms 220 are arranged to provide n-fold symmetry around the rotation axis 211.

A heater 230 is positioned at the outer end 222 of the support arms 220. In some embodiments, each support arm 220 has a heater 230. The center of the heaters 230 are located at a distance from the rotational axis 211 so that upon rotation of the center base 210 around rotation axis 211, the heaters 230 move in a circular path around rotation axis 211.

The heaters 230 have a support surface 231 configured to support a substrate to be processed on the top surface of the substrate. As used in this manner, a support surface, or other component, configured to support a substrate means that the surface is suitable for holding a substrate without damaging the substrate. In some embodiments, the heater 230 support surfaces 231 are substantially coplanar. As used in this manner, “substantially coplanar” means that the planes formed by the individual support surfaces 231 are within ±5°, ±4°, ±3°, ±2° or ±1° of the planes formed by the other support surfaces 231.

In some embodiments, the heaters 230 are positioned directly on the outer end 222 of the support arms 220. In some embodiments, as illustrated in the drawings, the heaters 230 are elevated above the outer end 222 of the support arms 220 by a heater standoff 234. The heater standoffs 234 can be any size and length to increase the height of the heaters 230. The term “pedestal” is used to refer to a heater standoff 234 with a support surface 231 connected to the top end of the standoff. The support surface 231 can be part of the heater 230 or part of a different component without a heating element.

In some embodiments, the support surface 231 comprises a thermally conductive body. In some embodiments, the thermally conductive body comprises Al, Ti, Si, oxides of Al, Ti or Si, nitrides of Al, Ti or Si, or combinations thereof. In some embodiments, the thermally conductive body comprises a plurality of plates.

In some embodiments, the substrate support comprises a ceramic coating on a top surface of the thermally conductive body. In some embodiments, the ceramic coating comprises AlOₓ, TiNₓ, TiOₓ, TiSiN, SiOₓ, SiN, AlN or combinations thereof. In some embodiments, the ceramic coating has a thickness in the range of from 20 Å to 5 μm. The ceramic coating can be applied by any of the method known to the skilled artisan. In some embodiments, the method includes but not limited to atomic layer deposition.

In some embodiments, a channel 236 is formed in one or more of the center base 210, the support arms 220 and/or the heater standoffs 234. The channel 236 can be used to route electrical connections for the heaters 230, electrical connections for an electrostatic chuck or to provide a gas flow.

The heaters 230 can be any suitable type of heater known to the skilled artisan. In some embodiments, the heater 230 is a resistive heater with one or more heating elements within a heater body.

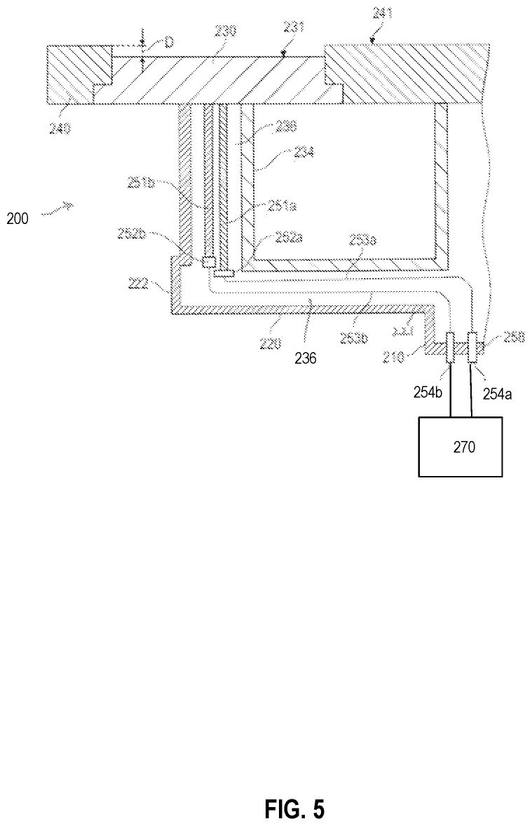

The heaters 230 of some embodiments include additional components. For example, the heaters may comprise an electrostatic chuck. The electrostatic chuck can include various wires and electrodes so that a substrate positioned on the heater support surface 231 can be held in place while the heater is moved. This allows a substrate to be chucked onto a heater at the beginning of a process and remain in that same position on that same heater while moving to different process regions. In some embodiments, the wires and electrodes are routed through the channels 236 in the support arms 220. FIG. 5 shows an expanded view of a portion of a support assembly 200 in which the channel 236 is shown. The channel 236 extends along the support arm 220 and the heater standoff 234. A first electrode 251a and second electrode 251b are in electrical communication with heater 230, or with a component inside heater 230 (e.g., a resistive wire or an electrostatic chuck). In the illustrated embodiment, a first wire 253a connects to first electrode 251a at first connector 252a; and a second wire 253b connects to second electrode 251b at second connector 252b. In some embodiments, there are more than two wires. For example, in an example embodiment with a heating element and an electrostatic chuck, at least two wires are in contact with the heating element and at least two wires are in contact with the electrostatic chuck.

In some embodiments, the heaters may comprise a vacuum chuck inlet configured to vacuum chuck a substrate. The vacuum chuck inlet is in fluid communication with a vacuum channel through which suction is created for vacuum chucking the substrate. In some embodiments, the vacuum channel extends to the support post within the thickness of the substrate support.

In some embodiments, a temperature measuring device (e.g., pyrometer, thermistor, thermocouple) is positioned within the channel 236 to measure one or more of the heater 230 temperature or the temperature of a substrate on the heater 230. In some embodiments, the control and/or measurement wires for the temperature measurement device are routed through the channel 236. In some embodiments, one or more temperature measurement devices are positioned within the processing chamber 100 to measure the temperature of the heaters 230 and/or a substrate on the heaters 230. Suitable temperature measurement devices are known to the skilled artisan and include, but are not limited to, optical pyrometers and contact thermocouples.

The wires can be routed through the support arms 220 and the support assembly 200 to connect with a power source (not shown). In some embodiments, the connection to the power source allows continuous rotation of the support assembly 200 without tangling or breaking the wires 253a, 253b. In some embodiments, as shown in FIG. 5, the first wire 253a and second wire 253b extend along the channel 236 of the support arm 220 to the center base 210. In the center base 210 the first wire 253a connects with center first connector 254a and the second wire 253b connects with center second connector 254b. The center connectors 254a, 254b can be part of a connection plate 258 so that power or electronic signals can pass through center connectors 254a, 254b. In the illustrated embodiment, the support assembly 200 can rotate continuously without twisting or breaking wires because the wires terminate in the center base 210. In some embodiments, the support assembly 200 is configured to allow rotation up to about 360° without twisting or breaking wires. A second connection is on the opposite side of the connection plate 258 (outside of the processing chamber).

In some embodiments, the wires are connected directly or indirectly to a power supply 270 or electrical component outside of the processing chamber through the channel 236. In embodiments of this sort, the wires have sufficient slack to allow the support assembly 200 to be rotated a limited amount without twisting or breaking the wires. In some embodiments, the support assembly 200 is rotated less than or equal to about 1080°, 990°, 720°, 630°, 360° or 270° before the direction of rotation is reversed. This allows the heaters 230 to be rotated through each of the stations 110 without breaking the wires.

In some embodiments, the heater 230 comprises a chiller plate. In some embodiments, the chiller plate comprises one or more heat exchange fluid channels. In some embodiments, the one or more heat exchange fluid channels are in fluid communication with one or more heat exchange fluid sources. In some embodiments, the heater is operatively connected to the one or more heat exchange fluid channels controlling the temperature of the heat exchange fluid within the heat exchange fluid channels.

Referring to FIG. 4, the heater 230 and support surface 231 can include one or more gas outlets (or openings 237) to provide a flow of backside gas. The backside gas may assist in the removal of the substrate from the support surface 231 or allow for other processes to occur, as described below. As shown in FIG. 4, the support surface 231 includes a plurality of openings 237 and a gas channel 238. The openings 237 and/or gas channel 238 can be in fluid communication with one or more of a vacuum source or a gas source. In some embodiments, the gas source comprises a purge gas or reactive gas. In embodiments of this sort, a gas line can be included to allow fluid communication of a gas source with the openings 237 and/or gas channel 238.

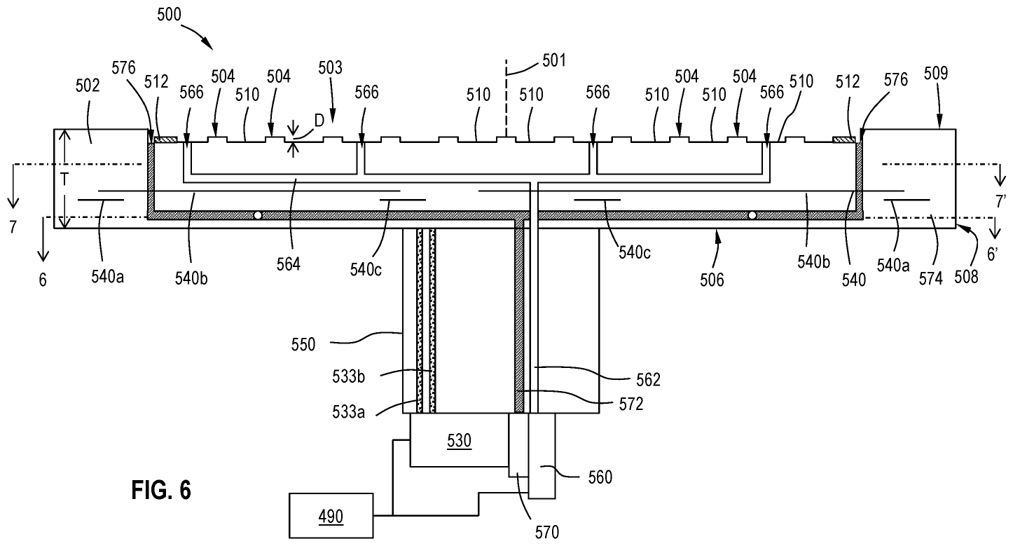

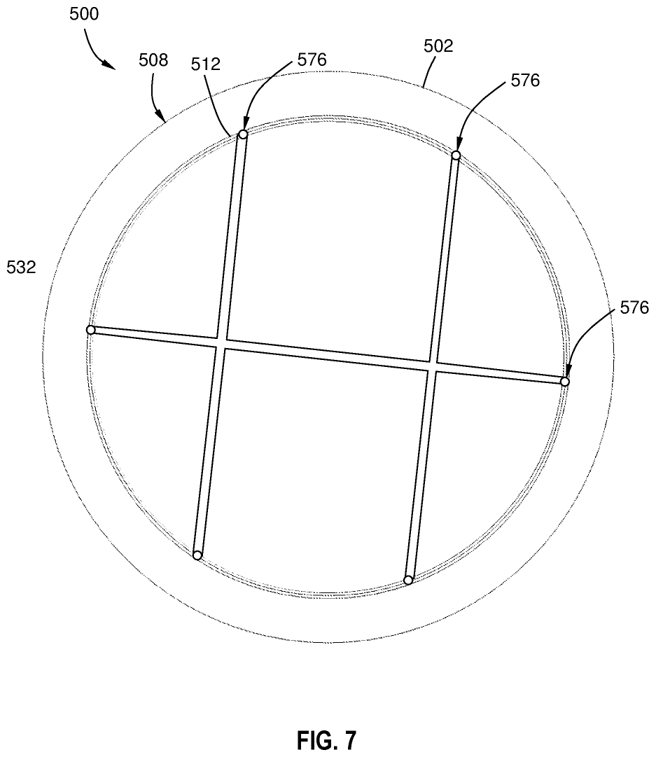

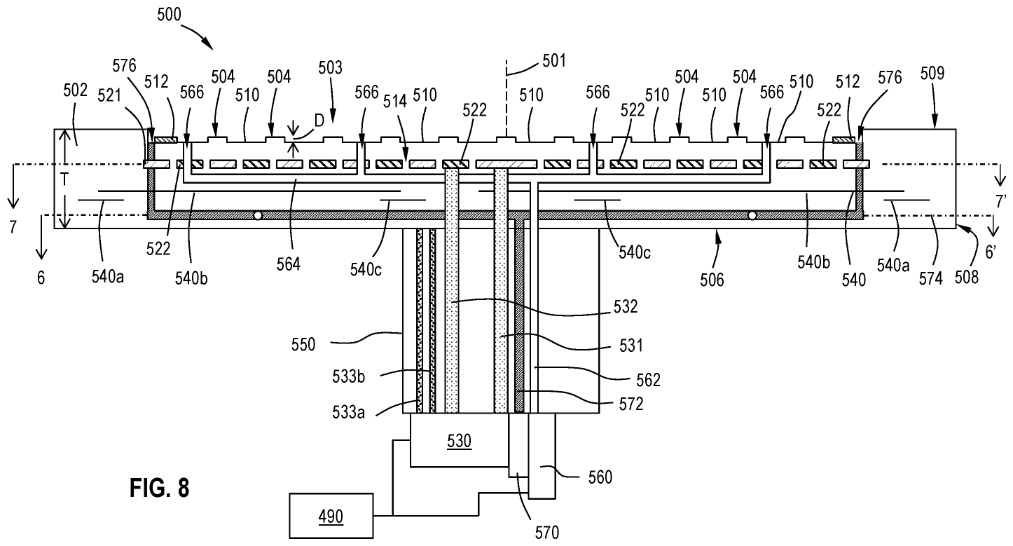

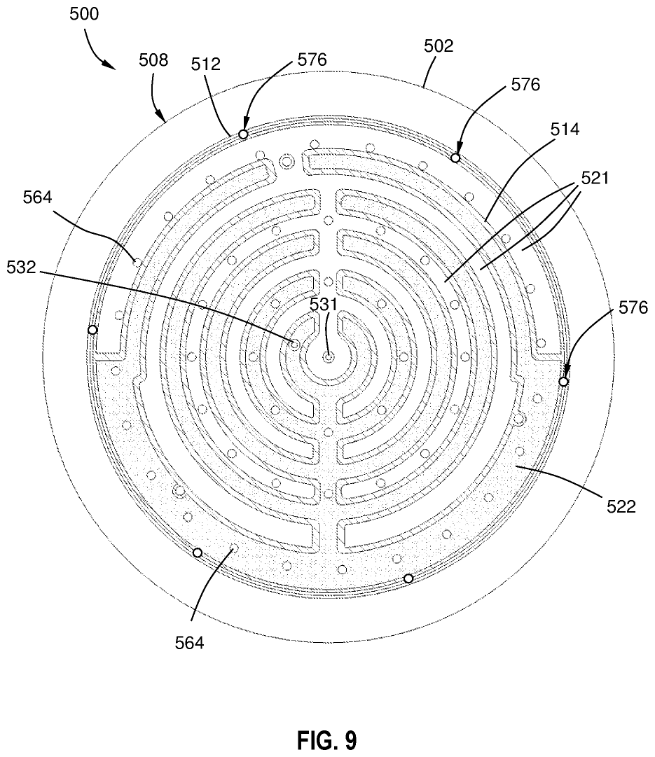

FIGS. 6 through 9 illustrate a substrate support 500 in accordance with one or more embodiments of the disclosure. FIGS. 6 and 8 show a cross-sectional view of a substrate support 500 or pedestal embodiments in a single-wafer configuration. However, the skilled artisan will recognize that the pedestal illustrated in FIGS. 6 and 8 are equivalent to the pedestals (the standoffs 234 and heater 230) shown in FIGS. 1 through 5. FIG. 7 illustrates schematic top views of a portion of a substrate support 500 similar to the one illustrated in FIG. 6 along line 6-6′ showing internal components. FIG. 9 illustrate schematic top views of a portion of a substrate support 500 similar to the one illustrated in FIG. 8 along line 7-7′ showing internal components. The embodiments illustrated in FIGS. 6 through 9 are merely representative of possible configurations and should not be taken as limiting the scope of the disclosure.

The substrate supports 500 have a body 502 with a support surface 504 and a bottom surface 506. The distance between the support surface 504 and bottom surface 506 define the thickness T of the body 502. In some embodiments, as shown in FIG. 6, the support surface 504 is recessed within a pocket 503 formed in the body 502. In some embodiments, the pocket 503 has a depth measured from the outer peripheral edge 509 of the substrate support 500 that is substantially the same as the thickness of a substrate to be processed. The term “substantially the same” means that the depth of the pocket 503 is within 95% to 105% of the thickness of the substrate. The substrate support 500 of some embodiments has a round profile with an outer peripheral face 508.

The skilled artisan will recognize that the body 502 and support surface 504 are equivalent to the heater 230 and support surface 231, respectively, shown in FIGS. 1-5. Accordingly, in some embodiments, the support surface 504 comprises a thermally conductive body. In some embodiments, the thermally conductive body comprises Al, Ti, Si, oxides of Al, Ti or Si, nitrides of Al, Ti or Si, or combinations thereof. In some embodiments, the thermally conductive body comprises a plurality of plates. In some embodiments, the substrate support 500 comprises a ceramic coating on a top surface of the thermally conductive body. In some embodiments, the ceramic coating comprises AlOₓ, TiNₓ, TiOₓ, TiSiN, SiOₓ, SiN, AlN or combinations thereof. In some embodiments, the ceramic coating has a thickness in the range of from 20 Å to 5 μm. The ceramic coating can be applied by any of the method known to the skilled artisan. In some embodiments, the method includes but not limited to atomic layer deposition

The support surface 504 has a plurality of fluid channels 510 extending a distance or depth D into the body 502. In some embodiments, the depth D that the fluid channels 510 extend into the body 502 is in the range of 0.01 mm to 5 mm, or in the range of 0.5 to 4 mm, or in the range of 1 to 3 mm. The regions (not numbered) between the fluid channels 510 are also referred to as mesas and in some embodiments supports the substrate during processing.

The field of fluid channels 510 is bounded around an outer edge (relative to a rotational axis 501) by a seal band 512. The substrate sits on the seal band 512 so that the back side of the substrate seals against the seal band 512. In some embodiments, the seal band 512 is a generally circular shape (which can be solid or broken) with an inner diameter slightly smaller than the diameter of a substrate to be processed. For example, the seal band 512 for a 300 mm substrate in some embodiments has an inner diameter less than 299 mm. In some embodiments, the seal band 512 has a top surface substantially even with the support surfaces 504.

In some embodiments, the body 502 further comprises at least one heating element 540 within the thickness T of the body 502. The at least one heating element 540 of some embodiments is connected to a power supply 530 through wires 533a, 533b.

The embodiment illustrated in FIG. 6 shows three heating element zones 540a, 540b, 540c spaced at different radii and at different positions along the rotational axis 501. The embodiment shows an outer zone 540a and an inner zone 540c on a first level in the body 502, and a center zone 540b on a second level in the body 502 closer to the support surface 504. The skilled artisan will recognize that the number and positioning of heating elements in the illustrated embodiment is merely one possible configuration and should not be taken as limiting the scope of the disclosure.

The substrate support 500 includes a support post 550 (equivalent to standoff 234) connected to the bottom surface 506 of the body 502. The support post 550 of some embodiments is hollow to contain the wires 533a, 533b, and any other connections or conduits (e.g., a purge gas conduit or plenum). In some embodiments, the support post 550 is a generally solid body with openings to house the wires 533a, 533b, and any other connections or conduits.

In some embodiments, as illustrated in FIG. 6, the substrate support 500 comprises a long edge purge channel 572. In some embodiments, as illustrated, the long edge purge channel 572 connects to a second purge leg 574 of the long edge purge channel 572 to split the flow of fluid into the different long edge purge channel outlets 576. In some embodiments, the long edge purge channel outlets 576 opens at an outer edge (relative to a rotational axis 501) of the support surface 504. In some embodiments, the long edge purge channel outlets 576 opens at an outer edge (relative to a rotational axis 501) of the support surface 504 by the seal band 512. In some embodiments, the support post 550 includes a plenum or cavity along the length of the long edge purge channel 572. In some embodiments, the long edge purge channel 572 is connected to a purge source 570 to allow a purge fluid to flow from the purge source 570 to the long edge purge channel outlet 576 through the long edge purge channel 572. In some embodiments, the long edge purge channel 572 provides a flow of purge fluid to the peripheral edge and/or backside of a substrate positioned on the support surface 504.

In some embodiments, the long edge purge channel 572 comprises Al, Ti, Si, oxides of Al, Ti or Si, nitrides of Al, Ti or Si, stainless steel, or combinations thereof. In some embodiments, the long edge purge channel 572 comprises a long edge purge channel coating. In some embodiments, the long edge purge channel coating prevents metal contamination on the substrate. In some embodiments, the long edge purge channel coating can be applied by any of the methods known to a skilled artisan. In some embodiments, the method includes atomic layer deposition. In some embodiments, ALD process tuning may include longer precursor dose time and/or longer purge time to ensure the long edge purge channel 572 is fully coated with desired materials. In some embodiments, the long edge purge channel coating has a thickness in a range of from 20 Å to 5 μm. In some embodiments, the long edge purge channel coating comprises AlOₓ, TiNₓ, TiOₓ, TiSiN, SiOₓ, SiN, AlN or combinations thereof.

The embodiments illustrated in FIG. 7 show plurality of long edge purge channel outlet 576 and second purge legs 574 within the thickness T of the body 502.

The embodiment illustrated in FIG. 6 includes a fluid line 562 in fluid communication with the fluid channels 510 formed in the support surface 504. The fluid line 562 of some embodiments is connected to a source 560 to allow a fluid to flow from the source 560 to the fluid channels 510 through the fluid line 562. In some embodiments, the plurality of fluid channel 510 is configured to circulate a fluid (a reactive gas and/or a purge gas) throughout the support surface 504. In some embodiments, the support post 550 includes a plenum or cavity along the length of the fluid line 562. In some embodiments, as illustrated, the fluid line 562 connects to a second leg 564 of the fluid line 562 to split the flow of fluid into the different openings 566 in the fluid channels 510. In some embodiments, the fluid line 562 provides a flow of fluid to the backside of a substrate positioned on the support surface 504.

In some embodiments of the disclosure include a controller 490 connected to one or more of the power supply 530, gas line 562 (or a valve on the gas line 562), or wires 533a, 533b.

In some embodiments, the substrate support 500 is an electrostatic chuck, as illustrated schematically in FIGS. 8 and 9. In some embodiments, the body 502 includes a first electrode 521 and a second electrode 522 configured to electrostatically chuck a substrate to the support surface 504. The first electrode 521 and second electrode 522 can be made of any suitable conductive material known to the skilled artisan. The cross-sectional view of FIG. 8 shows a single first electrode 521 and single second electrode 522 that appear split due to the cross-section angle. FIG. 9 shows a top down view of a similar configuration in which the two electrodes are visible. In some embodiments, there are more than two electrodes spaced throughout the body to provide multiple zones of electrostatic chucking force. For example, in some embodiments, the first electrode is split into an inner zone and an outer zone and the second electrode is a single electrode throughout. This arrangement allows for zonal control of the chucking force and electrical potential differential by using separate power supplies, or separate voltage sources of a single power supply.

The first electrode 521 and the second electrode 522 are separated by a gap 514. In some embodiments, the gap 514 comprises a dielectric material. In some embodiments, the dielectric material of the gap 514 is the same material as the body 502. In some embodiments, the dielectric material comprises aluminum oxide (Al₂O₃, also referred to as AlO) or aluminum nitride (AlN). The gap 514 prevents electrical shorting between the first electrode 521 and the second electrode 522.

FIG. 9 illustrated different embodiments of the electrostatic chuck using the first electrode 521 and second electrode 522, as viewed along line 7-7′ of FIG. 8. In some embodiments, the first electrode 521 is interdigitated with the second electrode 522 in a finger-joint like pattern. The shape of the electrodes can be any suitable shape.

In some embodiments, the support surface 504 optionally comprises lift pin openings 511. In some embodiments, the body 502 comprises a plurality of lift pins within the thickness T of the body 502. In some embodiments, lift pins may pass through lift pin openings 511 in the support surface 504 and lifting the substrate 505 from the support surface 504. In some embodiments, the plurality of lift pin openings 511 are configured to allow the plurality of lift pins to pass through each of the plurality of lift pin openings 511.

In some embodiments include the power supply 530 is further optionally connected to the first electrode 521 and second electrode 522 to generate the voltage differential between the electrodes 521, 522. The power supply 530 connects through transmission lines 531, 532 to the electrodes 521, 522. The transmission lines 531, 532 are electrically separated by any suitable insulator to prevent shorting or arcing. In some embodiments, transmission lines 531, 532 are part of a coaxial cable. In some embodiments, transmission lines 531, 532 are separate lines. The power supply 530 of some embodiments provides a first voltage (also referred to as potential) to the first electrode 521 and a second voltage to the second electrode 522 that is different from the first voltage. In some embodiments, the power supply 530 is configured to provide high voltage direct current (DC) and a low voltage alternating current (AC) component to the electrodes 521, 522.

In some embodiments, the power supply for the at least one heating element 540 is a different power supply 530 than connected to the first electrode 521 and second electrode 522.

As shown in FIG. 8, the support post 550 of some embodiments is hollow to contain the wires 533a, 533b, the optional transmission lines 531, 532 and any other connections or conduits (e.g., a purge gas conduit or plenum). In some embodiments, the support post 550 houses the wires 533a, 533b, the optional transmission lines 531, 532 and any other connections or conduits.

The embodiments illustrated in FIG. 9 show the plurality of the long edge purge channel outlet 576, and the plurality of purge lines 562 or second legs 564 spaced throughout the electrostatic chuck within the thickness T of the body 502.

In some embodiments of the disclosure include a controller 490 connected to one or more of the power supply 530, gas line 562 (or a valve on the gas line 562), wires 533a, 533b or the electrodes 521, 522.

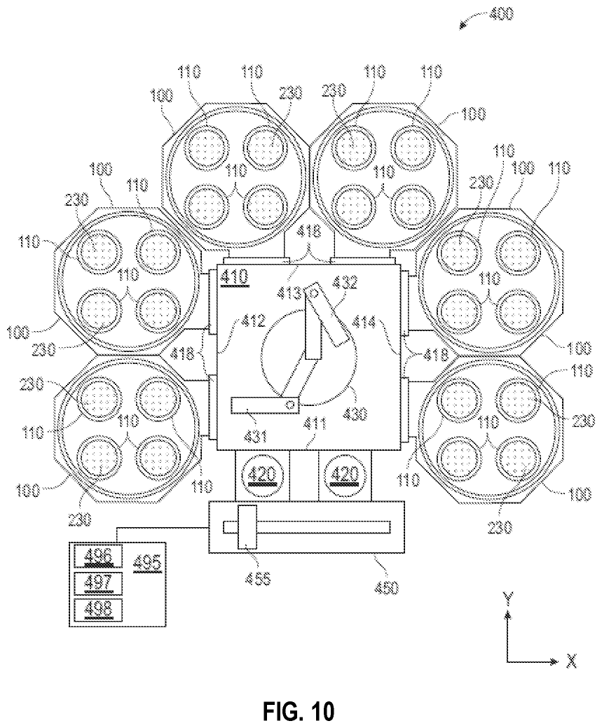

FIG. 10 shows a processing platform 400 in accordance with one or more embodiment of the disclosure. The embodiment shown in FIG. 10 is merely representative of one possible configuration and should not be taken as limiting the scope of the disclosure. For example, in some embodiments, the processing platform 400 has different numbers of one or more of the processing chambers 100, buffer stations 420 and/or robot 430 configurations than the illustrated embodiment.

The exemplary processing platform 400 includes a central transfer station 410 which has a plurality of sides 411, 412, 413, 414. The transfer station 410 shown has a first side 411, a second side 412, a third side 413 and a fourth side 414. Although four sides are shown, those skilled in the art will understand that there can be any suitable number of sides to the transfer station 410 depending on, for example, the overall configuration of the processing platform 400. In some embodiments, there the transfer station 410 has three sides, four sides, five sides, six sides, seven sides or eight sides.

The transfer station 410 has a robot 430 positioned therein. The robot 430 can be any suitable robot capable of moving a substrate during processing. In some embodiments, the robot 430 has a first arm 431 and a second arm 432. The first arm 431 and second arm 432 can be moved independently of the other arm. The first arm 431 and second arm 432 can move in the x-y plane and/or along the z-axis. In some embodiments, the robot 430 includes a third arm (not shown) or a fourth arm (not shown). Each of the arms can move independently of other arms.

The embodiment illustrated includes six processing chambers 100 with two connected to each of the second side 412, third side 413 and fourth side 414 of the central transfer station 410. Each of the processing chambers 100 can be configured to perform different processes.

The processing platform 400 can also include one or more buffer station 420 connected to the first side 411 of the central transfer station 410. The buffer stations 420 can perform the same or different functions. For example, the buffer stations may hold a cassette of substrates which are processed and returned to the original cassette, or one of the buffer stations may hold unprocessed substrates which are moved to the other buffer station after processing. In some embodiments, one or more of the buffer stations are configured to pre-treat, pre-heat or clean the substrates before and/or after processing.

The processing platform 400 may also include one or more slit valves 418 between the central transfer station 410 and any of the processing chambers 100. The slit valves 418 can open and close to isolate the interior volume within the processing chamber 100 from the environment within the central transfer station 410. For example, if the processing chamber will generate plasma during processing, it may be helpful to close the slit valve for that processing chamber to prevent stray plasma from damaging the robot in the transfer station.

The processing platform 400 can be connected to a factory interface 450 to allow substrates or cassettes of substrates to be loaded into the processing platform 400. A robot 455 within the factory interface 450 can be used to move the substrates or cassettes into and out of the buffer stations. The substrates or cassettes can be moved within the processing platform 400 by the robot 430 in the central transfer station 410. In some embodiments, the factory interface 450 is a transfer station of another cluster tool (i.e., another multiple chamber processing platform).

A controller 495 may be provided and coupled to various components of the processing platform 400 to control the operation thereof. The controller 495 can be a single controller that controls the entire processing platform 400, or multiple controllers that control individual portions of the processing platform 400. For example, the processing platform 400 of some embodiments comprises separate controllers for one or more of the individual processing chambers 100, central transfer station 410, factory interface 450 and/or robots 430.

In some embodiments, the processing chamber 100 further comprises a controller 495 connected to the plurality of substantially coplanar support surfaces 231 configured to control one or more of the first temperature or the second temperature. In one or more embodiments, the controller 495 controls a movement speed of the support assembly 200 (see FIG. 2).

In some embodiments, the controller 495 includes a central processing unit (CPU) 496, a memory 497, and support circuits 498. The controller 495 may control the processing platform 400 directly, or via computers (or controllers) associated with particular process chamber and/or support system components.

The controller 495 may be one of any form of general-purpose computer processor that can be used in an industrial setting for controlling various chambers and sub-processors. The memory 497 or computer readable medium of the controller 495 may be one or more of readily available memory such as random access memory (RAM), read only memory (ROM), floppy disk, hard disk, optical storage media (e.g., compact disc or digital video disc), flash drive, or any other form of digital storage, local or remote. The memory 497 can retain an instruction set that is operable by the processor (CPU 496) to control parameters and components of the processing platform 400.

The support circuits 498 are coupled to the CPU 496 for supporting the processor in a conventional manner. These circuits include cache, power supplies, clock circuits, input/output circuitry and subsystems, and the like. One or more processes may be stored in the memory 498 as software routine that, when executed or invoked by the processor, causes the processor to control the operation of the processing platform 400 or individual processing chambers in the manner described herein. The software routine may also be stored and/or executed by a second CPU (not shown) that is remotely located from the hardware being controlled by the CPU 496.

Some or all of the processes and methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 495 has one or more configurations to execute individual processes or sub-processes to perform the method. The controller 495 can be connected to and configured to operate intermediate components to perform the functions of the methods. For example, the controller 495 can be connected to and configured to control one or more of gas valves, actuators, motors, slit valves, vacuum control or other components.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

In the foregoing specification, embodiments of the disclosure have been described with reference to specific exemplary embodiments thereof. It will be evident that various modifications may be made thereto without departing from the broader spirit and scope of the embodiments of the disclosure as set forth in the following claims. The specification and drawings are, accordingly, to be regarded in an illustrative sense rather than a restrictive sense.

What is claimed is:

1. A substrate support, comprising:
a thermally conductive body having a top surface, a bottom surface and an outer edge;
a ceramic coating on the top surface of the thermally conductive body, wherein the substrate support is configured to support a substrate to be processed on the top surface of the thermally conductive body; and
a plurality of long edge purge channel outlet opening at the outer edge of the thermally conductive body, each of the plurality of long edge purge channel outlet is in fluid communication with a long edge purge channel, wherein the long edge purge channel is coated with a long edge purge channel coating.

2. The substrate support of claim 1, wherein the thermally conductive body comprises Al, Ti, Si, oxides of Al, Ti or Si, nitrides of Al, Ti or Si, or combinations thereof.

3. The substrate support of claim 1, wherein the ceramic coating comprises AlOₓ, TiNₓ, TiOₓ, TiSiN, SiOₓ, SiN, AlN or combinations thereof.

4. The substrate support of claim 1, wherein the long edge purge channel comprises Al, Ti, Si, oxides of Al, Ti or Si, nitrides of Al, Ti or Si, stainless steel, or combinations thereof.

5. The substrate support of claim 1, wherein the long edge purge channel coating comprises AlOₓ, TiNₓ, TiOₓ, TiSiN, SiOₓ, SiN, AlN or combinations thereof.

6. The substrate support of claim 1 further comprising a first electrode and a second electrode configured to electrostatically chuck a substrate on the top surface of the substrate support.

7. The substrate support of claim 1, further comprising a vacuum chuck inlet for vacuum chucking the substrate, the vacuum chuck inlet is in fluid communication with a vacuum channel.

8. The substrate support of claim 1, further comprising:
a first heating element disposed within an outer zone of the thermally conductive body;
a second heating element disposed within an inner zone of the thermally conductive body; and
a third heating element disposed within a central zone of the thermally conductive body.

9. A substrate support assembly, comprising:
a substrate support, the substrate support comprising a thermally conductive body having a top surface, a bottom surface and an outer edge, the substrate support is configured to support a substrate to be processed on the top surface of the thermally conductive body; and
a support post coupled to the substrate support comprising a long edge purge channel coated with a long edge purge channel coating, the long edge purge channel is in fluid communication with a long edge purge outlet that opens at the outer edge of the thermally conductive body.

10. The substrate support assembly of claim 9, wherein the long edge purge channel comprises Al, Ti, Si oxides of Al, Ti or Si, nitrides of Al, Ti or Si, stainless steel, or combinations thereof.

11. The substrate support assembly of claim 9, wherein the long edge purge channel coating comprises AlOₓ, TiNₓ, TiOₓ, TiSiN, SiOₓ, SiN, AlN or combinations thereof.

12. The substrate support assembly of claim 9, wherein the substrate support further comprising a ceramic coating on the top surface of the thermally conductive body.

13. The substrate support of claim 9, wherein the thermally conductive body comprises Al, Ti, Si, oxides of Al, Ti or Si, nitrides of Al, Ti or Si, or combinations thereof.

14. The substrate support of claim 12, wherein the ceramic coating comprises AlOₓ, TiNₓ, TiOₓ, TiSiN, SiOₓ, SiN, AlN or combinations thereof.

15. The substrate support assembly of claim 9, further comprising:
a first heating element is disposed within an outer zone of the thermally conductive body;
a second heating element is disposed within an inner zone of the thermally conductive body; and
a third heating element is disposed within a central zone of the thermally conductive body.

16. The substrate support assembly of claim 9, further comprising a first electrode and a second electrode configured to electrostatically chuck a substrate on a top surface of the substrate support.

17. The substrate support of claim 9, further comprising a vacuum chuck inlet for vacuum chucking the substrate, the vacuum chuck inlet is in fluid communication with a vacuum channel.

18. A processing chamber, comprising:
a chamber body; and
a substrate support within the chamber body, comprising:
a thermally conductive body having a top surface, a bottom surface and an outer edge, the thermally conductive body comprises Al, Ti, Si, oxides of Al, Ti or Si, nitrides of Al, Ti or Si, or combinations thereof;
a ceramic coating on the top surface of the thermally conductive body, wherein the substrate support is configured to support a substrate to be processed on the top surface of the thermally conductive body, the ceramic coating comprising AlOₓ, TiNₓ, TiOₓ, TiSiN, SiOₓ, SiN, AlN or combinations thereof; and
a plurality of long edge purge channel outlet opening at the outer edge of the thermally conductive body, each of the plurality of long edge purge channel outlet is in fluid communication with a long edge purge channel, wherein the long edge purge channel is coated with a long edge purge channel coating, the long edge purge channel coating comprising AlOₓ, TiNₓ, TiOₓ, TiSiN, SiOₓ, SiN, AlN or combinations thereof;
a first heating element disposed within an outer zone of the thermally conductive body;
a second heating element disposed within an inner zone of the thermally conductive body; and
a third heating element disposed within a central zone of the thermally conductive body.

19. The processing chamber of claim 18, further comprising a first electrode and a second electrode configured to electrostatically chuck a substrate on a top surface of the substrate support.

20. The processing chamber of claim 18, further comprising a vacuum chuck inlet for vacuum chucking the substrate, the vacuum chuck inlet is in fluid communication with a vacuum channel.
